(19) United States
(12) Patent Application Publication
(10) Pub. No.: US 2024/0153796 A1
(43) Pub. Date: May 9, 2024

(54) SUBSTRATE PROCESSING APPARATUS

(71) Applicant: Tokyo Electron Limited, Tokyo (JP)

(72) Inventor: Yusuke KIKUCHI, Yamanashi (JP)

(21) Appl. No.: 18/383,637

(22) Filed: Oct. 25, 2023

(30) Foreign Application Priority Data
Nov. 7, 2022 (JP) 2022-178210

(51) Int. Cl. H01L 21/67; H01L 21/683; H01L 21/687

(52) U.S. Cl. CPC H01L 21/6719; H01L 21/67103; H01L 21/67248; H01L 21/6833; H01L 21/68742

(57) ABSTRACT

A substrate processing apparatus includes a processing container, a stage having an electrostatic chuck that attracts and holds a substrate inside the processing container, the stage being configured to be rotatable, a refrigeration device arranged at a lower side of the stage and configured to cool the electrostatic chuck while being in contact with or be separated from the stage, a lift device configured to vertically move the refrigeration device, and a peripheral member provided around the refrigeration device and coated with a material having lower emissivity than a base material of the peripheral member.

### CROSS-REFERENCE TO RELATED APPLICATIONS

The present application is based on and claims priority from Japanese Patent Application No. 2022-178210, filed on Nov. 7, 2022, with the Japan Patent Office, the disclosure of which is incorporated herein in its entirety by reference.

### TECHNICAL FIELD

The present disclosure relates to a substrate processing apparatus.

### BACKGROUND

Japanese Patent No. 6788393, for example, proposes a method of forming a copper film using a sputtering method in a physical vapor deposition (PVD) apparatus. The method proposed in Japanese Patent No. 6788393 includes a step of forming a base film, which is a titanium nitride film, tungsten film, or tungsten nitride film, along a surface of an insulating film of a workpiece and a step of forming a copper film on the base film cooled to a temperature of 209 Kelvin or less.

Japanese Patent No. 6559347, for example, provides a holding device capable of holding a processing target object freely rotatably while cooling it to an extremely low temperature within a vacuum environment.

### SUMMARY

According to an aspect of the present disclosure, there is provided a substrate processing apparatus including a processing container, a stage having an electrostatic chuck configured to attract and hold a substrate inside the processing container, the stage being configured to be rotatable, a refrigeration device arranged at a loser side of the stage and configured to cool the electrostatic chuck while being in contact with or be separated from the stage, a lifting device configured to vertically move the refrigeration device, and a peripheral member provided around the refrigeration device and coated with a material having lower emissivity than a base material of the peripheral member.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating an example configuration during rotation of a stage of a substrate processing apparatus according to an embodiment.

FIG. 2 is a cross-sectional view illustrating an example configuration during cooling of the stage of the substrate processing apparatus according to the embodiment.

FIGS. 3A to 3E are diagrams illustrating an operation of the stage (electrostatic chuck) according to the embodiment.

FIG. 4 is a partial enlarged cross-sectional view of a bellows at the bottom of the stage according to the embodiment.

FIG. 5A illustrates the temperature of the electrostatic chuck after substrate unloading from the substrate processing apparatus according to a reference example, and FIG. 5B illustrates the temperature of the electrostatic chuck after substrate unloading from the substrate processing apparatus according to the embodiment.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for carrying out the present disclosure will be described with reference to the drawings. In each drawing, the same reference numerals may be given to the same components, and redundant descriptions may be omitted.

In this specification, orientations such as parallel, right angle, orthogonal, horizontal, vertical, up-and-down, and left-and-right may allow for slight deviations that do not compromise the effectiveness of the embodiments. The shapes of corners are not limited to right angles and may include rounded or curved shapes. Terms such as parallel, right angle, orthogonal, horizontal, vertical, circular, and coincident may also encompass variations that are substantially parallel, substantially right angle, substantially orthogonal, substantially horizontal, substantially vertical, substantially circular, and substantially coincident.

[Substrate Processing Apparatus]

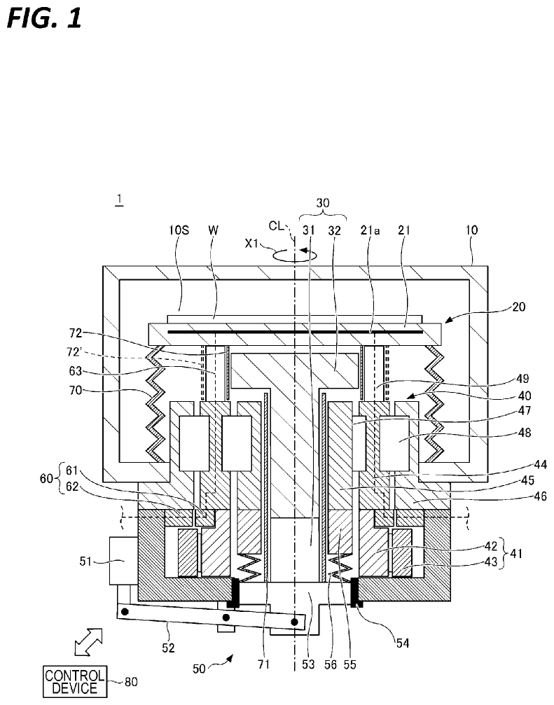

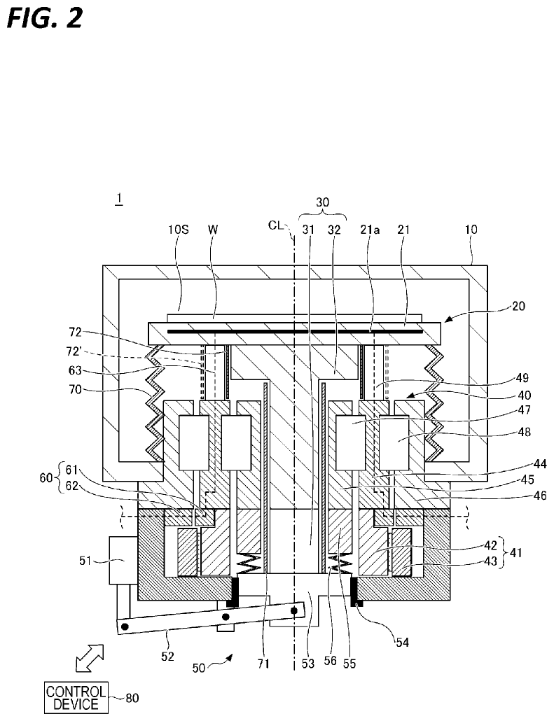

An example of a substrate processing apparatus 1 according to an embodiment will be described with reference to FIGS. 1 and 2. FIG. 1 is a cross-sectional view illustrating an example configuration during rotation of a stage 20 of the substrate processing apparatus according to the embodiment. FIG. 2 is a cross-sectional view illustrating an example configuration during cooling of the stage 20 of the substrate processing apparatus 1 according to the embodiment.

The substrate processing apparatus 1 may be, for example, a chemical vapor deposition (CVD) apparatus or atomic layer deposition (ALD) apparatus that supplies a processing gas into a processing container 10 to perform a desired processing (e.g., film forming processing) on a substrate W. Further, the substrate processing apparatus 1 may be, for example, a PVD apparatus that supplies a processing gas into the processing container 10 and sputters a target provided inside the processing container 10 to perform a desired processing (e.g., film forming processing) on the substrate W.

The substrate processing apparatus 1 includes the processing container 10, the stage 20 for placing the substrate W inside the processing container 10, a refrigeration device 30, a rotation device 40 for rotating the stage 20, and a lifting device 50 for vertically moving the refrigeration device 30. The stage 20 on which the substrate W is placed is provided inside the processing container 10. Further, the substrate processing apparatus 1 includes a control device 80 for controlling various devices such as the refrigeration device 30, rotation device 40, and lifting device 50.

The processing container 10 defines an internal space 10S. The processing container 10 is configured in such a way that the internal space 10S thereof is reduced in pressure to an ultra-high vacuum by operating an exhaust device (not illustrated) such as a vacuum pump. Further, the processing container 10 is configured to receive a desired gas used for a substrate processing, which is supplied through a gas supply pipe (not illustrated) communicating with a processing gas supply device (not illustrated).

The stage 20 is made of a material with high thermal conductivity (e.g., Cu). The stage 20 includes an electrostatic chuck 21. The electrostatic chuck 21 has a chuck electrode 21a embedded in a dielectric film. The substrate processing apparatus 1 includes a slip ring 60 for supplying power to the chuck electrode 21a of the rotating stage 20. Each chuck electrode 21a is designed to be provided with a predetermined potential through the slip ring 60 and a wiring 63. With this configuration, the substrate W may be held on a placement surface by electrostatic attraction using the electrostatic chuck 21, and may be fixed to an upper surface (placement surface) of the stage 20.

The refrigeration device 30 is configured to be in contact with or separated from the stage 20 at the bottom of the stage 20 and to cool the stage 20 (electrostatic chuck 21). The refrigeration device 30 is constructed by stacking a refrigerator 31 and a refrigeration thermal medium 32. The refrigeration thermal medium 32 may also be referred to as a cold link. The refrigerator 31 holds the refrigeration thermal medium 32 and cools an upper surface of the refrigeration thermal medium 32 to an extremely low temperature. In terms of cooling capacity, the refrigerator 31 may utilize a Gifford-McMahon (GM) cycle. The refrigeration thermal medium 32 is fixed on the refrigerator 31, with an upper portion thereof accommodated inside the processing container 10. The refrigeration thermal medium 32 is made of a material with high thermal conductivity (e.g., Cu), and has a substantially cylindrical external shape. The refrigeration thermal medium 32 is positioned such that the center thereof coincides with the central axis CL of the stage 20.

Further, the stage 20 is freely rotatably supported by the rotation device 40. The rotation device 40 includes a rotation drive device 41, a fixed shaft 45, a rotational shaft 44, a housing 46, ferrofluid seals 47 and 48, and a stand 49.

The rotation drive device 41 is a direct drive motor that includes a rotor 42 and a stator 43. The rotor 42 has a substantially cylindrical shape extending coaxially with the rotational shaft 44 and is fixed to the rotational shaft 44. The stator 43 has a substantially cylindrical shape with an inner diameter larger than an outer diameter of the rotor 42. The rotation drive device 41 may take forms other than the direct drive motor, and may take a form including a servo motor and a transmission belt.

The rotational shaft 44 has a substantially cylindrical shape extending coaxially with the central axis CL of the stage 20. The fixed shaft 45 is provided at the radial inner side of the rotational shaft 44. The fixed shaft 45 has a substantially cylindrical shape extending coaxially with the central axis CL of the stage 20. The housing 46 is provided at the radial outer side of the rotational shaft 44. The housing 46 has a substantially cylindrical shape extending coaxially with the central axis CL of the stage 20 and is fixed to the processing container 10.

Further, the ferrofluid seal 47 is provided between an outer peripheral surface of the fixed shaft 45 and an inner peripheral circle of the rotational shaft 44. The ferrofluid seal 47 serves not only to freely rotatably support the rotational shaft 44 relative to the fixed shaft 45, but also to seal between the outer peripheral surface of the fixed shaft 45 and the inner peripheral circle of the rotational shaft 44, thus separating the internal space 10S of the processing container 10, which is freely reducible in pressure, from an external space of the processing container 10. Further, the ferrofluid seal 48 is provided between an inner peripheral surface of the housing 46 and an outer peripheral circle of the rotational shaft 44. The ferrofluid seal 48 serves not only to freely rotatably support the rotational shaft 44 relative to the housing 46, but also to seal between the inner peripheral surface of the housing 46 and the outer peripheral circle of the rotational shaft 44, thus separating the internal space 10S of the processing container 10, which is freely reducible in pressure, from the external space of the processing container 10. This allows the rotational shaft 44 to be freely rotatably supported by the fixed shaft 45 and the housing 46. Further, the refrigeration thermal medium 32 is inserted through a substantially cylindrical first shield member 71 at the radial inner side of the fixed shaft 45.

The stand 49 is vertically provided between the rotational shaft 44 and the stage 20, and is configured to transmit the rotation of the rotational shaft 44 to the stage 20. A substantially cylindrical second shield member 72 is provided at the inner peripheral side of the stand 49. A substantially cylindrical third shield member 72′ may be provided at the outer peripheral side of the stand 49 (indicated by dashed lines in FIGS. 1 and 2). At least one of the first shield member 71, second shield member 72, and third shield member 72′ may be arranged.

With the above configuration, when the rotor 42 of the rotation drive device 41 rotates, the rotational shaft 44, the stand 49, and the stage 20 rotate relative to the refrigeration thermal medium 32 in the X1 direction (see, e.g., FIG. 1).

Further, the refrigeration device 30 is freely vertically movably supported by the lifting device 50. The lifting device 50 includes an air cylinder 51, a link mechanism 52, a refrigeration device support 53, a linear guide 54, a fixing part 55, and a bellows 56.

The air cylinder 51 is a mechanical device in which a rod linearly moves by air pressure. The link mechanism 52 converts the linear motion of the rod of the air cylinder 51 into the vertical motion of the refrigeration device support 53. Further, the link mechanism 52 has a lever structure with one end connected to the air cylinder 51 and the other end connected to the refrigeration device support 53. This allows for the generation of a significant press force with a small thrust force of the air cylinder 51. The refrigeration device support 53 supports the refrigeration device 30 (refrigerator 31 and refrigeration thermal medium 32). Further, the refrigeration device support 53 is guided in the vertical movement direction by the linear guide 54.

The fixing part 55 is fixed to a lower surface of the fixed shaft 45. The bellows 56 having a substantially cylindrical shape is provided between a lower surface of the fixing part 55 and an upper surface of the refrigeration device support 53 to surround the refrigerator 31. The bellows 56 is a vertically freely expandable and contractible accordion-like structure made of a metal. This arrangement ensures that the fixing part 55, the bellows 56, and the refrigeration device support 53 seal between an inner peripheral surface of the fixed shaft 45 and an outer peripheral circle of the refrigeration thermal medium 32, thus separating the internal space 10S of the processing container 10, which is freely reducible in pressure, from the external space of the processing container 10. Further, the lower surface side of the refrigeration device support 53 is adjacent to the external space of the processing container 10, and a region of the upper surface side of the refrigeration device support 53 surrounded by the bellows 56 is adjacent to the internal space 10S of the processing container 10.

The substrate processing apparatus 1 includes the slip ring 60 made of a metal below the rotational shaft 44 and the housing 46 to supply a direct current voltage (DC voltage) to the chuck electrode 21a.

The slip ring 60 includes a rotating body 61 including a metal ring and a stationary body 62 including a brush. The rotating body 61 has a substantially cylindrical shape extending coaxially with the rotational shaft 44 and is fixed to a lower surface of the rotational shaft 44. The stationary body 62 has a substantially cylindrical shape with an inner diameter slightly larger than an outer diameter of the rotating body 61, and is fixed to a lower surface of the housing 46. The slip ring 60 is electrically connected to a DC power supply (not illustrated), and supplies power from the DC power supply to the wiring 63 through the brush of the stationary body 62 and the metal ring of the rotating body 61. With this configuration, it is possible to apply a potential to the chuck electrode 21a from the DC power supply without causing twisting or other issues in the wiring 63. The slip ring 60 may have a structure other than a brush structure, and may have, for example, a non-contact power supply structure or a structure without mercury or with a conductive liquid, among others.

The processing container 10 is provided at the top thereof with a cathode part (not illustrated), which is provided to face the stage 20 and is configured to sputter a plurality of targets. A power supply connected to the cathode part may be a DC power supply and/or a radio frequency (RF) power supply, but is not limited thereto. At least one of a DC voltage and a RF voltage may be applied to the cathode part from the DC power supply and/or the RF power supply.

A bellows 70 is provided between a lower surface of the stage 20 and a bottom surface of the processing container 10 to cover the refrigeration device 30. The bellows 70 is a vertically freely expandable and contractible accordion-like structure made of a metal. This arrangement ensures that the stage 20, bellows 70, and processing container 10 separate a space below the stage 20 where the refrigeration device 30 is located from the internal space 10S of the processing container 10 which is freely reducible in pressure outside the bellows 70. The bellows 70, first shield member 71, second shield member 72, third shield member 72′, and bellows 56 are examples of peripheral members around the refrigeration device 30, and are members coated with a material having lower emissivity than base materials of the peripheral members. These peripheral members around the refrigeration device 30 will be described later.

The control device 80 is, for example, a computer, and includes a central processing unit (CPU), a random access memory (RAM), a read only memory (ROM), an auxiliary storage, among others. The CPU operates based on programs stored in the ROM or the auxiliary storage and controls an operation of the plasma processing apparatus 1. The control device 80 may control the substrate processing apparatus 1 through, for example, wired or wireless communication mechanisms.

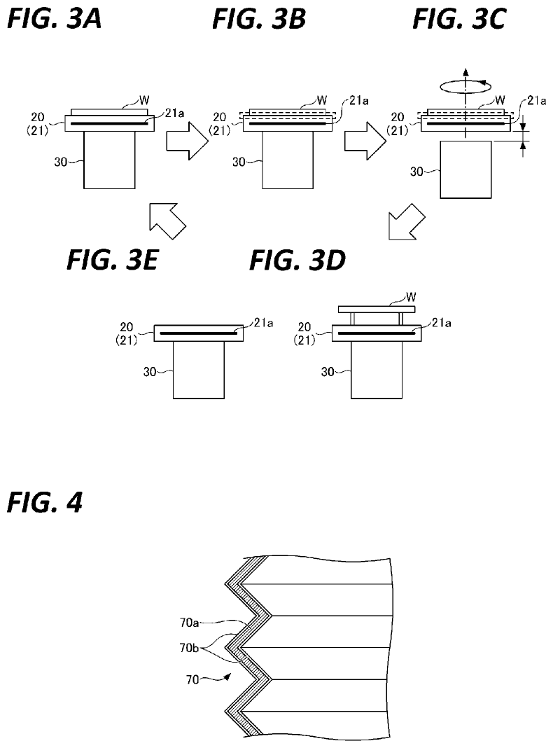

An operation of the stage 20 (electrostatic chuck 21) in the substrate processing apparatus 1 having the above configuration will be described with reference to FIGS. 3A to 3E. FIGS. 3A to 3E are diagrams illustrating an operation of the stage 20 (electrostatic chuck 21) according to the embodiment. During loading of the substrate W as illustrated in FIG. 3A, the control device 80 brings the stage 20 into contact with the refrigeration device 30. In this state, the temperature of the stage 20 is cooled to an extremely low temperature, which is a set temperature for a substrate processing. After loading the substrate W, the control device 80 applies a DC voltage from a DC power supply (not illustrated) to the chuck electrode 21a to electrostatically attract the substrate W onto the electrostatic chuck 21, as illustrated in FIG. 3B. Furthermore, a heat transfer gas may be supplied between the substrate W and the stage 20 to enhance the efficiency of heat transfer.

During a processing of the substrate W, as illustrated in FIGS. 3C and 1, the control device 80 opens the lifting device 50 (air cylinder 51) to separate the stage 20 and the refrigeration device 30 from each other. The control device 80 controls the rotation device 40 (rotation drive device 41: FIG. 1) to rotate the stage 20 (electrostatic chuck 21) holding the substrate W by electrostatic attraction. This may improve the in-plane uniformity of the substrate W in the processing (e.g., Cu film forming processing).

After the processing of the substrate W, the control device 80 stops the rotation device 40 (rotation drive device 41) to stop the rotation of the stage 20. At the same time, the control device 80 applies a DC voltage with a polarity opposite to that during chucking from the DC power supply (not illustrated) to the chuck electrode 21a to dechuck the substrate W, and then detaches the substrate W from the electrostatic chuck 21 by a supporting pin to unload the substrate W by a transfer arm (not illustrated), as illustrated in FIG. 3D.

The control device 80 cools the stage 20 during a waiting time for a processing of the next substrate W. At that time, as illustrated in FIGS. 3E and 2, the cooling efficiency of the stage 20 may be increased by controlling the lifting device 50 (air cylinder 51) to press the refrigeration device 30 against the stage 20. The control device 80 may control the lifting device 50 (air cylinder 51) to bring the refrigeration device 30 into contact with the stage 20 after stopping the rotation of the stage 20 and before unloading the substrate W, as illustrated in FIG. 3D.

When cooling the substrate W, the substrate W is cooled to an extremely low temperature of approximately 72 Kelvin (K), i.e. approximately −200° C. However, the extremely low temperature is not limited to −200° C., and may range from −233° C. to −123° C. For example, when forming a Cu film on the substrate W once the substrate W has been cooled to the extremely low temperature, the agglomeration of Cu particles may be reduced, and the sheet resistance and surface roughness of the Cu film may be reduced compared to film formation at room temperature, resulting in the formation of a high-quality Cu film.

In addition to the Cu film, in magnetic tunnel junction (MTJ) elements used in MRAMs and HDD heads, the substrate W is cooled to the extremely low temperature to promote the amorphization of a crystalline structure of a magnetic layer, which determines the characteristics of MRAMs in multilayer thin films using various types of materials. Then, film formation is performed on the substrate W cooled to the extremely low temperature.

However, the time required to cool the stage 20 (and the substrate W) to the extremely low temperature depends on the contact efficiency between contact surfaces of the stage 20 (electrostatic chuck 21) and the refrigeration device 30 (refrigeration thermal medium 32), which may cause a deterioration in productivity. It may be desirable to increase the contact efficiency between the contact surfaces of the stage 20 and the refrigeration device 30 to shorten the cooling time, but it is difficult to modify the structure (hardware) of the contact surfaces so as to increase the contact efficiency beyond the current state.

It could be seen from experiments that during the unloading of the substrate W as illustrated in FIG. 3D, the temperature of the stage 20 increased by approximately 1.5 Kelvin (K), compared to that before the loading of the substrate W, due to heat input from the substrate W, heat input by sputtering of the cathode part (not illustrated) during the film forming processing, and inflow of a room-temperature gas from the outside. In FIG. 3E, if the temperature of the stage 20 is not completely cooled to the extremely low temperature, which is the set temperature, before starting the processing of the next substrate W, and a processing of the next substrate W in FIG. 3A is started in such an incompletely cooled state, heat accumulation occurs in the stage 20, causing a continuous increase in the temperature of the stage 20 while a certain number of substrates W is processed. Therefore, it becomes challenging to maintain the consistent film quality for each substrate W.

Therefore, to maintain the consistent film quality for each substrate W, it may be necessary to return the temperature of the stage 20 to the extremely low temperature, which is the set temperature for the substrate processing, before the loading of the substrate W in FIG. 3A, as illustrated in FIG. 3E. However, even during cooling in FIG. 3E, radiant heat continues to be transferred to the refrigeration device 30 from the peripheral members provided around the refrigeration device 30.

Accordingly, in the substrate processing apparatus 1 according to the present embodiment, the peripheral members around the refrigeration device 30 are coated with a material having lower emissivity than base materials of the peripheral members. This allows for a reduction in the transfer of radiant heat to the refrigeration device 30 from the peripheral members surrounding the refrigeration device 30.

For example, by applying a material with low emissivity to the surface of a base material of the peripheral member around the refrigeration device 30, the transfer amount of radiant heat from the peripheral member to the refrigeration device 30 is reduced, and the cooling efficiency between the refrigeration device 30 and the stage 20 is increased. This may reduce the time required to return the temperature of the stage 20 to the set extremely low temperature (hereinafter referred to as “recovery time”) after unloading the substrate W and before starting the processing of the next substrate W, thereby enhancing productivity.

For example, as an example of the peripheral member around the refrigeration device 30, FIG. 4 illustrates a partial enlarged cross-sectional view of the bellows 70 which is located at the bottom of the stage 20 and surrounds the refrigeration device 30. A base material 70a of the bellows 70 is a metal such as stainless steel (SUS). The bellows 70 is coated with a material having lower emissivity than the base material. Specifically, the base material 70a of the bellows 70 is coated with gold (gold plating). Gold is less likely to form an oxide film, and thus, is a plating material capable of stably reducing the transfer of radiant heat. The bellows 70 is positioned between the lower surface of the stage 20 and the bottom surface of the processing container 10. Thus, it is possible to reduce the radiant heat transferred from the outside of the bellows 70 to the refrigeration device 30 through the base material of the bellows 70 using the plated gold having lower emissivity than the base material. This may increase the cooling efficiency of the stage 20 by the refrigeration device 30, resulting in a shortened recovery time for the temperature of the stage 20.

In the present embodiment, gold plating is also performed on the first shield member 71 adjacent to the refrigeration device 30. A base material of the first shield member 71 is stainless steel and is coated with gold, which is a material having lower emissivity than the base material.

Further, in the present embodiment, base materials of the second shield member 72 and/or the third shielding member 72′ surrounding respectively the inner periphery and outer periphery of the stand 49, which transmits the rotation of the rotation device 40 to the stage base 20, are stainless steel. Then, the base materials are coated with gold, which is a material having lower emissivity than the base materials.

Therefore, the radiant heat transferred from the outside to the refrigeration device 30 through the base materials of the first shield member 71, the second shield member 72, and/or the third shield member 72′ may be reduced by the plated gold on each shield member. This may increase the cooling efficiency of the stage 20 by the refrigeration device 30, resulting in a shortened recovery time for the temperature of the stage 20.

Furthermore, in the present embodiment, a base material of the bellows 56, which is screwed to the refrigeration device support 53 between the fixing part 55 that secures the rotation device 40 and the refrigeration device support 53 that supports the refrigeration device 30, may be coated with gold. This allows for a reduction in the transfer of radiant heat from the outside of the bellows 56 to a space inside the bellows 56 by the plated gold on the bellows 56.

The equation for radiant heat between two flat plates is given by Equation (1).

$$Q = A σ ( \frac{1}{\frac{1}{{ε}_{h}} + \frac{1}{{ε}_{c}} - 1} ) ( {T}_{h}^{4} - {T}_{c}^{4} ) \qquad ( 1 )$$

Here, Q is the amount of heat, A is the surface area of each of the two flat plates facing each other, σ is the Steffen-Boltzmann constant, c is the emissivity, T is the temperature, h is the high temperature surface, and c is the low temperature surface. For example, in a case of the first shield member 71, A is the surface area of a surface of the first shield member 71 facing the refrigeration device 30. The emissivity of gold is sufficiently lower than that of stainless steel or copper, and when gold plating is performed the peripheral member, εh in Equation (1) may be made sufficiently smaller than εc compared to a case where gold plating is not performed to the peripheral member. Thus, by performing gold plating on the peripheral member, it is possible to sufficiently reduce the amount of heat Q (radiant heat) as indicated by Equation (1), compared to a case where gold plating is not performed on the peripheral member.

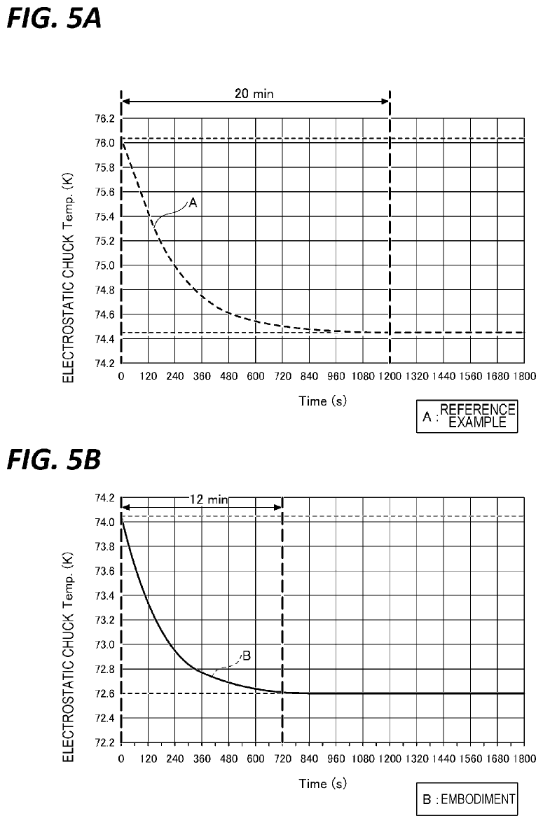

FIG. 5A illustrates the temperature of the stage (electrostatic chuck 21) after unloading the substrate W from the substrate processing apparatus according to a reference example in which gold plating is not performed on the peripheral member, and FIG. 5B illustrates the temperature of the stage (electrostatic chuck 21) after unloading the substrate W from the substrate processing apparatus 1 according to the embodiment.

The substrate processing apparatus 1 according to the reference example in FIG. 5A corresponds to a case where gold plating is not performed on the peripheral members (bellows 70, bellows 56, first shield member 71, second shield member 72, and third shield member 72) around the refrigeration device 30. The substrate processing apparatus 1 according to the embodiment in FIG. 5B corresponds to a case where gold plating is not performed on the peripheral members (e.g., bellows 70, bellows 56, first shield member 71, second shield member 72, and third shield member 72) around the refrigeration device 30.

In FIGS. 5A and 5B, the horizontal axis represents the time, and the vertical axis represents the temperature of the electrostatic chuck 21. The temperature of the electrostatic chuck 21 is the temperature of a placement surface of the electrostatic chuck 21 in contact with the substrate W. The temperature at time 0 seconds in FIGS. 5A and 5B is the temperature of the placement surface of the electrostatic chuck 21 during the unloading of the substrate W. At time 0 seconds in FIGS. 5A and 5B, the temperature of the placement surface of the electrostatic chuck 21 increased by approximately 1.5 K due to the unloading of the substrate W. Then, in the substrate processing apparatus according to the reference example in FIG. 5A, the recovery time required to return to the set temperature for the substrate processing was 20 minutes. In other words, the recovery time of 20 minutes was required each time one substrate W was processed.

In contrast, in the substrate processing apparatus 1 according to the present embodiment in FIG. 5B, the recovery time required to return to the set temperature for the substrate processing was shortened to 12 minutes. Thus, in the substrate processing apparatus 1 according to the present embodiment, the cooling efficiency between the refrigeration device 30 and the stage 20 may be increased, which may shorten the recovery time of the temperature of the stage 20 (electrostatic chuck 21) to approximately ⅔ of the recovery time in the case of the substrate processing apparatus according to the reference example, and may enhance productivity.

As described above, according to the substrate processing apparatus 1 of the present embodiment, it is possible to reduce the recovery time required to return the temperature of the stage 20 after the unloading of the substrate W to the set temperature for the substrate processing.

According to one aspect, it is possible to shorten the time required to return the temperature of a stage after substrate unloading to a set temperature for a substrate processing.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a processing container;
a stage having an electrostatic chuck that attracts and holds a substrate inside the processing container, the stage being configured to be rotatable;
a refrigerator arranged at a lower side of the stage and configured to cool the electrostatic chuck while being in contact with or separated from the stage;
a lift configured to vertically move the refrigerator; and
a peripheral plate provided around the refrigerator and coated with a material having lower emissivity than a base material of the peripheral member.

2. The substrate processing apparatus according to claim 1, wherein the material having lower emissivity than the base material of the peripheral plate is gold.

3. The substrate processing apparatus according to claim 1, wherein the peripheral plate is a bellows surrounding a periphery of the refrigerator.

4. The substrate processing apparatus according to claim 3, wherein the bellows is provided between a lower surface of the stage and a bottom surface of the processing container.

5. The substrate processing apparatus according to claim 1, wherein the peripheral plate is a cylindrical shield adjacent to the refrigerator.

6. The substrate processing apparatus according to claim 1, further comprising:
a rotator configured to rotate the stage; and
a stand provided between the rotator and the stage and configured to transmit rotation of the rotator to the stage,
wherein the peripheral plate is a cylindrical shield surrounding an inner periphery and/or an outer periphery of the stand.

7. The substrate processing apparatus according to claim 3, further comprising a rotator configured to rotate the stage,
wherein the bellows is provided between a fixing part that fixes the rotator and a refrigerator support that supports the refrigerator.
